(19) United States
(12) Patent Application Publication
(10) Pub. No.: US 2004/0023124 A1
(43) Pub. Date: Feb. 5, 2004

(54) Photolithography process with hybrid chromeless phase shift mask

(75) Inventors: Chin-Lung Lin, Hsinchu Hsien (TW); Chuen-Huei Yang, Taipei (TW); Wen-Tien Hung, Taipei City (TW)

Correspondence Address: J C PATENTS, INC., 4 VENTURE, SUITE 250, IRVINE, CA, 92618, US

(73) Assignee: UNITED MICROELECTRONICS CORP., HSINCHU (TW)

(21) Appl. No.: 10/065,145

(22) Filed: Sep. 20, 2002

(30) Foreign Application Priority Data
Aug. 2, 2002 (TW) 91117409

(51) Int. Cl. G03F 1/08; G03F 7/20

(52) U.S. Cl. 430/5; 430/311

(57) ABSTRACT

The present invention relates to a photolithography process using hybrid chromeless phase shift masks. A mask having a gate pattern formed on a base plate is provided. A 180-degree shifter layer is formed at critical dimension locations of the base plate. The mask of the present invention can be used for transferring the gate pattern to a photoresist layer in the exposure process.

### CROSS REFERENCE TO RELATED APPLICATIONS

This application claims the priority benefit of Taiwan application serial no. 91117409, filed Aug. 2, 2002.

### BACKGROUND OF INVENTION

1. Field of Invention

The present invention relates to a photolithography process. More particularly, the present invention relates to a photolithography process using hybrid chromeless phase shift masks.

2. Description of Related Art

As the integration of the integrated circuits (ICs) increases, the device sizes of the ICs need to shrink. Photolithography is one of the essential processes in semiconductor manufacture. Photolithography is widely applied in many process steps for fabricating metal-oxide-semiconductor (MOS) devices, including pattern transferring for gate regions and doping regions. In order to increase the resolution of photolithography, many technologies, such as, phase shift mask (PSM) and optical proximity correction (OPC), have been developed.

The basic concept of phase shift mask is to add a shifter layer between adjacent apertures of the mask patterns, causing a 180-degree phase shifting of the light. The shifter layer can reverse the phase and induce interference, thus enhancing resolution for the images at the wafer. The shifter layer can be designed with a specific thickness and a refractive index in order to cause a 180-degree phase shift, so that diffraction from adjacent apertures can be cancelled out. As a result, the exposure resolution is increased and uniformity for critical dimensions of the device is improved.

FIG. 1 is a top view of a device layout, while FIGS. 2 and 3 are top views of two masks respectively used in alternating phase shift mask (PSM) technology for the device of FIG. 1.

Referring to FIG. 1, the device layout includes a gate structure 102 on a provided substrate 100 and doping regions 104, 106 formed in the substrate 100 and on both sides of the gate structure 102. The critical dimension of the gate structure 102 needs to be precisely controlled. Therefore, the alternating PSM technology is used to increase resolution and improve uniformity.

Referring to FIG. 2, a 180-degree shifter layer 202 and a 0-degree shifter layer 204 are formed on a base plate 204 having chromium coating. The 180-degree layer 202 and the 0-degree shifter layer 204 are disposed on both sides of critical dimension locations of the gate structure 102.

The mask of FIG. 2 is used as an exposure mask for the first exposure step. Afterwards, the second exposure step is performed using the mask of FIG. 3 as an exposure mask. As shown in FIG. 3, the layout of the mask is to form a gate pattern 302 on a transparent base plate 300. The gate pattern 302 corresponds to the gate structure 102 in FIG. 1. That is, most of the transparent base plate 300 is not covered by chromium coating and is thus a 0-degree shifter region, except for the region covered by the gate pattern 302. After performing the first and the second exposure steps, the gate pattern is transferred to the photoresist layer on the wafer.

The prior art alternating PSM technology requires double exposure steps, which are more complicated and time inefficient. Furthermore, the design of masks is much more elaborated since two different masks are needed to match one another.

### SUMMARY OF INVENTION

The present invention provides a photolithography process using hybrid chromeless phase shift masks, thus improving the prior art problems present in alternating PSM technology by using double exposure steps.

The present invention relates to a photolithography process using hybrid chromeless phase shift masks, for simplifying the photolithography process and reducing its cost.

As embodied and broadly described herein, the present invention relates to a photolithography process using hybrid chromeless phase shift masks. A mask having a gate pattern formed on a base plate is provided. A 180-degree shifter layer is formed at critical dimension locations of the base plate, while non-critical dimension locations of the gate pattern on the base plate are covered by chromium coating. The critical dimension locations are 180-degree shifter layers made of, for example, quartz materials. Except for the gate pattern, the rest of the base plate is a 0-degree shifter region. The mask of the present invention can be used for transferring the gate pattern to a photoresist layer in the exposure process.

The present invention provides a method for fabricating the hybrid chromeless phase shift mask. After providing a transparent base plate covering by a layer of chromium coating, a gate pattern is formed by patterning the chromium coating layer and by removing a specific thickness from a portion of the base plate. The resultant gate pattern is a two-layered structure including the patterned chromium coating layer and a portion of the base plate with a specific thickness. A photolithography step is performed to remove the chromium coating layer on the critical dimension locations to expose the base plate. The exposed base plate at the critical dimensioned locations function as a 180-degree shifter layer. The non-gate-pattern locations of the base plate function as a 0-degree shifter layer.

The mask designed according to the present invention can be used in the exposure step for transferring the pattern to a photoresist layer on a chip.

The present invention employs the hybrid chromeless phase shift mask in photolithography process for patterning the gate structure. High resolution in critical dimension with high uniformity is achieved by using only one mask and performing single exposure step.

The present invention employs the hybrid chromeless phase shift mask in photolithography process for patterning the gate structure by using only one single mask, so that the design and fabrication of the mask can be simplified and cost is thus reduced.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a top view of a device layout, while FIGS. 2 and 3 are top views of two masks respectively used in alternating phase shift mask (PSM) technology for the device of FIG. 1 according to the prior art;

FIG. 4 is a top view of a mask for the device of FIG. 1 in the process using hybrid chromeless phase shift mask according to one preferred embodiment of this invention;

FIGS. 5A-5C are cross-sectional views of the mask layout in FIG. 4 according to cross-section I-I″, showing the manufacture process according to one preferred embodiment of this invention; and

FIGS. 6A-6B are light oscillation distribution diagrams for passing shifter layers of different line widths.

### DETAILED DESCRIPTION

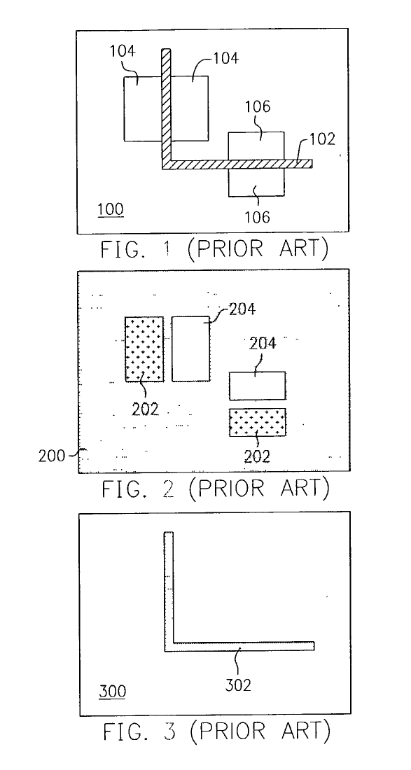

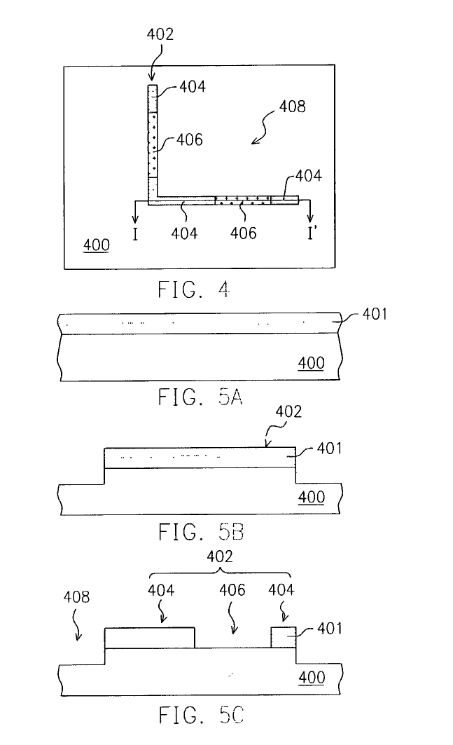

FIG. 4 is a top view of a mask for the device of FIG. 1 in the process using hybrid chromeless phase shift mask according to one preferred embodiment of this invention. Referring back to FIG. 1, the device layout includes a gate structure 102 on a provided substrate 100 and doping regions 104, 106 formed in the substrate 100 and on both sides of the gate structure 102. The critical dimension for portions the gate structure 102 that has the doping regions 104, 106 on both sides needs to be precisely controlled.

As shown in FIG. 4, a gate pattern 402 (corresponding to the gate structure 102 in FIG. 1) is formed on a transparent base plate 400. Within the gate pattern 402, a 180-degree shifter layer is formed at specific locations 406 (i.e. critical dimension locations) of the base plate, which correspond to the portions of the gate structure 102 that has doping regions 104, 106 on both sides.

For example, the transparent base plate 400 is a transparent quartz base plate. Except for the critical dimension locations 406 are transparent 180-degree shifter layers, other locations 404 (i.e. non-critical dimension locations) of the gate pattern 402 on the base plate 400 are covered by chromium coating. The 180-degree shifter layer is made of, for example, quartz materials. The critical dimension locations have a line-width of, for example, 0.13 microns or less, preferably, 0.1 microns or less. Except for the gate pattern 402, the rest of the base plate 400 is a 0-degree shifter region.

FIGS. 5A-5C are cross-sectional views of the mask layout in FIG. 4 according to cross-section I-I″, showing the manufacture process according to one preferred embodiment of this invention using hybrid chromeless phase shift mask.

Referring to FIG. 5A, a transparent base plate 400 is covered with an opaque layer of chromium coating 401. The base plate is made of, for example, quartz materials.

In FIG. 5B, a gate pattern 402 is formed by patterning the chromium coating layer 401 and by removing a specific thickness from a portion of the base plate 400. The method for patterning the chromium coating layer 401 and removing a specific thickness from a portion of the base plate 400 is, for example, forming a patterned resist layer (not shown) on the chromium coating layer 401 and then performing an etching process using the patterned resist layer as a mask. The resultant gate pattern 402 is a two-layered structure including the patterned chromium coating layer 401 and a portion of the base plate 400 with a specific thickness. The design of the specific thickness will be described in the following paragraph.

Referring to FIG. 5C, the chromium coating layer 401 on the critical dimension locations 406 is removed to expose the base plate 400. The base plate 400 within the critical dimensioned locations 406 is thicker than the other locations 408 (i.e. non-gate-pattern locations) that are not within the gate pattern of the base plate. The difference of thickness between the critical dimensioned locations 406 and the non-gate-pattern locations 408 is especially designed, so that the critical dimensioned locations 406 can function as a 180-degree shifter layer and the non-gate-pattern locations 408 can function as a 0-degree shifter layer.

The mask designed according to the present invention can be used in the exposure step for transferring the pattern to a photoresist layer on a chip.

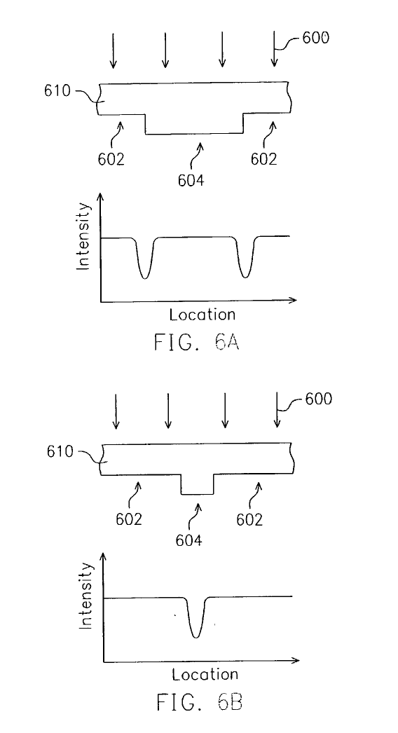

FIGS. 6A-6B are light oscillation distribution diagrams for passing shifter layers of different line widths.

As shown in FIG. 6A, a mask 610 having a 180-degree shifter layer 604 and a 0-degree shifter layer 602 is provided. The width of the 180-degree shifter layer 604 is larger than 0.15 microns. As light 600 pass the mask 610, two light oscillations are formed corresponding to both sides of the 180-degree shifter layer 604 in the mask 610.

Referring to FIG. 6B, as if the width of the 180-degree shifter layer 604 is smaller than 0.13 microns; after light 600 pass the mask 610, only one light oscillation is present corresponding to the 180-degree shifter layer 604 in the mask 610. That is because the previous two oscillations are emerged into one oscillation due to the close distance. The present invention takes advantage of this single oscillation distribution in FIG. 6B for the critical dimension locations within the gate pattern.

The mask design of the present invention combines the technologies of chromeless mask and phase shift mask. Because the chromeless mask technology is suitable for fine-line fabricating processes, chromium coating in the critical dimension locations of the. gate pattern is replace by a 180-degree shifter layer. The non-critical dimension locations of the gate pattern are still covered by chromium coating. Therefore, the resolution and the uniformity of critical dimensions are increased. Moreover, the design of the mask is simplified and less exposure steps are used, thus saving time and reducing cost.

In conclusion, the present invention has the following advantages:

1. The present invention employs the hybrid chromeless phase shift mask in photolithography process for patterning the gate structure. High resolution in critical dimension with high uniformity is achieved by using only one mask and performing single exposure step.

2.Because only one single mask is used for gate patterning, the design and fabrication of the mask can be simplified and cost is thus reduced.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A photolithography process using a hybrid chromeless phase shift mask, comprising the following steps:providing a mask having a gate pattern, wherein a 180-degree shifter layer is formed at a critical dimension location of the gate pattern; and performing an exposure process foe transferring the gate pattern to a photoresist layer.

2. The process of claim 1, wherein the gate pattern has a non-critical dimension location and the non-critical dimension location is an opaque region.

3. The process of claim 2, wherein the opaque region is covered by a chromium coating film.

4. The process of claim 1, wherein the 180-degree shifter layer is made of quartz materials.

5. The process of claim 1, wherein the mask has a non-gate-pattern location that is not covered the gate pattern and the non-gate-pattern location is a 0- degree shifter region.

6. A method for fabricating a hybrid chromeless phase shift mask, comprising the following steps:providing a transparent base plate covering by a chromium coating film; patterning the chromium coating film and removing a portion of the transparent base plate to form a gate pattern; and removing the chromium coating film at a critical dimension location of the gate pattern to expose the transparent base plate, wherein the exposed transparent base plate is a 180-degree shifter layer.

7. The method of claim 6, wherein the transparent base plate is made of quartz materials.

8. The method of claim 6, wherein the transparent base plate has a non-gate-pattern location that is not covered the gate pattern and the non-gate-pattern location is a 0-degree shifter region.

9. The method of claim 6, the step of patterning the chromium coating film and removing a portion of the transparent base plate includes a photolithography process.

10. The method of claim 6, the step of removing the chromium coating film at a critical dimension location of the gate pattern to expose the transparent base plate includes a photolithography process.
